(19) United States
(12) Patent Application Publication
(10) Pub. No.: US 2025/0361633 A1
(43) Pub. Date: Nov. 27, 2025

(54) SOLID OXIDE CELL, AND METHOD OF MANUFACTURING AND METHOD OF OPERATING SAME

(71) Applicant: POSTECH RESEARCH AND BUSINESS DEVELOPMENT FOUNDATION, Pohang-si (KR)

(72) Inventors: Ji Hwan AN, Pohang-si (KR); Hyong June KIM, Pohang-si (KR); Kyoung jae JU, Pohang-si (KR); Sung Eun JO, Pohang-si (KR)

(21) Appl. No.: 18/923,925

(22) Filed: Oct. 23, 2024

(30) Foreign Application Priority Data
May 22, 2024 (KR) 10-2024-0066420

(51) Int. Cl. C25B 11/093; C25B 1/02; H01M 4/90; H01M 4/92

(52) U.S. Cl. CPC C25B 11/093; C25B 1/02; H01M 4/9025; H01M 4/9075; H01M 4/925

(57) ABSTRACT

A solid oxide cell comprising: a substrate comprising a first region and a second region; and a catalyst material deposited in the form of particles in each of the first region and the second region, and comprising a first catalyst material group deposited in the first region and a second catalyst material group deposited in the second region, wherein power is applied to an electrode including the substrate, based on operating in a first mode, a first form of a catalyst material of the first catalyst material group and a second form of a catalyst material of the second catalyst material group are different, and based on operating in a second mode, the first form of the first catalyst material group and a third form of a catalyst material of the second catalyst material group are different.

### CROSS-REFERENCE TO RELATED APPLICATION

This application claims priority under 35 U.S.C § 119 to Korean Patent Application No. 10-2024-0066420 filed on May 22, 2024, in the Korean Intellectual Property Office, the entire contents of which are hereby incorporated by reference.

### TECHNICAL FIELD

The disclosure relates to a solid oxide cell, a method of manufacturing the solid oxide cell, and a method of operating the solid oxide cell, and more particularly, to a solid oxide cell capable of operating as a solid oxide fuel cell and solid oxide electrolysis, and a method of manufacturing and a method of operating the same.

### BACKGROUND

The contents set forth in this section merely provide background information on the present embodiments and do not constitute prior art.

A solid oxide cell is one of the power generation cells that produce electrical energy based on the electrochemical reaction of hydrogen and oxygen. A solid oxide cell is an environmentally friendly energy conversion device that can continuously produce electricity under the supply of hydrogen and oxygen.

Since the electrodes of a solid oxide cell have the structural characteristic of being porous, a deposition method using an aqueous solution containing a catalyst is used to deposit a catalyst in the solid oxide cell.

On the other hand, because catalysts are expensive and require precise thickness control during deposition, there has been a need for efficiently managing the usage of catalysts.

### SUMMARY

It is an object of the present disclosure to provide a solid oxide cell, and a method of manufacturing and a method of operating the same, which can reduce the amount of catalyst used and improve the catalytic reactivity by depositing a catalyst in the electrodes of the solid oxide cell using an atomic layer deposition (hereinafter, ALD).

The objects of the present disclosure are not limited to the objects mentioned above, and other objects and advantages of the present disclosure that have not been mentioned can be appreciated by the following description and will be more clearly understood by the embodiments of the present disclosure. Further, it will be readily appreciated that the objects and advantages of the present disclosure may be realized by the means set forth in the claims and combinations thereof.

According to some aspects of the disclosure, a solid oxide cell comprises: a substrate comprising a first region and a second region, and a catalyst material deposited in the form of particles in each of the first region and the second region, and comprising a first catalyst material group deposited in the first region and a second catalyst material group deposited in the second region, wherein power is applied to an electrode including the substrate, based on operating in a first mode, a first form of a catalyst material of the first catalyst material group and a second form of a catalyst material of the second catalyst material group are different, and based on operating in a second mode, the first form of the first catalyst material group and a third form of a catalyst material of the second catalyst material group are different.

According to some aspects, the second form and the third form are different.

According to some aspects, based on operating alternately in the first mode and the second mode, the second form and the third form are maintained in the form of particles having a size within a certain range.

According to some aspects, the second form and the third form have a size of 8 nm to 10 nm.

According to some aspects, the first region and the second region are porous regions.

According to some aspects, based on operating in the first mode, the catalyst material of the second catalyst material group is inserted into a grain boundary of a material contained in the second region, and based on having switched from the first mode to the second mode, the catalyst material of the second catalyst material group is precipitated from the grain boundary of the material contained in the second region.

According to some aspects, based on operating in the first mode, the catalyst material of the first catalyst material group is maintained in the form of an alloy with a metallic material of the first region, and based on having switched from the first mode to the second mode, the catalyst material of the first catalyst material group is maintained in the form of the alloy with the metallic material of the first region.

According to some aspects of the disclosure, a method of manufacturing and operating a solid oxide cell, comprises: providing a substrate comprising a first region containing a first material and a second region containing a second material, depositing a catalyst material in the first region and the second region in the form of particles using atomic layer deposition (ALD), and operating in one of a first mode and a second mode by applying power to an electrode including the substrate.

According to some aspects, the catalyst material comprises a first catalyst material group deposited in the first region in the form of particles and a second catalyst material group deposited in the second region in the form of particles, and wherein the operating in one of the first mode and the second mode by applying power to the electrode including the substrate comprises: operating in the first mode so that a first form of a catalyst material of the first catalyst material group and a second form of a catalyst material of the second catalyst material group are different; and operating in the second mode so that the first form of the first catalyst material group and a third form of a catalyst material of the second catalyst material group are different.

According to some aspects, the second form and the third form are different.

According to some aspects, the operating in one of the first mode and the second mode by applying power to the electrode including the substrate comprises: operating alternately in the first mode and the second mode so that the second form and the third form are maintained in the form of particles having a size within a certain range.

According to some aspects, the first region and the second region are porous regions.

According to some aspects, the catalyst material comprises a first catalyst material group deposited in the first region in the form of particles and a second catalyst material group deposited in the second region in the form of particles, and wherein the operating in one of the first mode and the second mode by applying power to the electrode including the substrate comprises: operating in the first mode so that a catalyst material of the second catalyst material group is inserted into a grain boundary of the second material; and switching from the first mode to the second mode so that the catalyst material of the second catalyst material group is precipitated from the grain boundary of the second material.

According to some aspects, in the operating in the first mode, a catalyst material of the first catalyst material group is maintained in the form of an alloy with a metallic material of the first region, and in the switching from the first mode to the second mode, the catalyst material of the first catalyst material group is maintained in the form of the alloy with the metallic material of the first region.

According to some aspects of the disclosure, a method of manufacturing and operating a solid oxide cell, comprises: providing a substrate comprising a first region and a second region in which a catalyst material is deposited in the form of particles, operating in one of a first mode and a second mode by applying power to an electrode including the substrate, wherein the catalyst material comprises a first catalyst material group deposited in the first region in the form of particles and a second catalyst material group deposited in the second region in the form of particles, and wherein the operating in one of the first mode and the second mode by applying power to the electrode including the substrate comprises, operating in the first mode so that a first form of a catalyst material of the first catalyst material group and a second form of a catalyst material of the second catalyst material group are different; and operating in the second mode so that the first form of the first catalyst material group and a third form of a catalyst material of the second catalyst material group are different.

According to some aspects, further comprising: depositing the catalyst material in the first region and the second region in the form of particles using atomic layer deposition (ALD)

According to some aspects, the operating in one of the first mode and the second mode by applying power to the electrode including the substrate comprises: operating alternately in the first mode and the second mode so that the second form and the third form are maintained in the form of particles having a size within a certain range.

According to some aspects, the first region and the second region are porous regions.

According to some aspects, the operating in the first mode comprises setting to the first mode so that the catalyst material of the second catalyst material group is inserted into a grain boundary of a material contained in the second region, and wherein the operating in one of the first mode and the second mode by applying power to the electrode including the substrate comprises: switching from the first mode to the second mode so that the catalyst material of the second catalyst material group is precipitated from the grain boundary of the material contained in the second region.

According to some aspects, in the operating in the first mode, the catalyst material of the first catalyst material group is maintained in the form of an alloy with a metallic material of the first region, and in the switching from the first mode to the second mode, the catalyst material of the first catalyst material group is maintained in the form of the alloy with the metallic material of the first region.

Aspects of the disclosure are not limited to those mentioned above and other objects and advantages of the disclosure that have not been mentioned can be understood by the following description and will be more clearly understood according to embodiments of the disclosure. In addition, it will be readily understood that the objects and advantages of the disclosure can be realized by the means and combinations thereof set forth in the claims.

The solid oxide cell, and the method of manufacturing and the method of operating the same of the present disclosure can reduce the amount of catalyst used and improve the catalytic reactivity by depositing a catalyst in the electrodes of the solid oxide cell using an atomic layer deposition (hereinafter, ALD).

In addition to the contents described above, specific effects of the present disclosure will be described together while describing the following specific details for carrying out the present disclosure.

### BRIEF DESCRIPTION OF THE DRAWINGS

FIG. 1 is a diagram for describing a solid oxide cell in accordance with an embodiment of the present disclosure.

FIG. 2 is an enlarged view of the region m of FIG. 1.

FIG. 3 is an enlarged view of the region m in FIG. 1.

FIG. 4 is an enlarged view of the region m in FIG. 1.

FIG. 5 is an enlarged view of the region m in FIG. 1.

FIG. 6 is a diagram for describing a method of manufacturing and operating a solid oxide cell in accordance with an embodiment of the present disclosure.

FIGS. 7 to 9 are diagrams for describing step S100 in FIG. 6.

FIGS. 10 and 11 are diagrams for describing step S200 of FIG. 6.

FIG. 12 is a diagram for describing step S300 of FIG. 6.

FIG. 13 is a plot for describing the effect of a solid oxide cell in accordance with an embodiment of the present disclosure.

FIG. 14 is a plot for describing the effect of the method of manufacturing and operating a solid oxide cell in accordance with an embodiment of the present disclosure.

### DETAILED DESCRIPTION OF THE PREFERRED EMBODIMENTS

The terms or words used in the disclosure and the claims should not be construed as limited to their ordinary or lexical meanings. They should be construed as the meaning and concept in line with the technical idea of the disclosure based on the principle that the inventor can define the concept of terms or words in order to describe his/her own inventive concept in the best possible way. Further, since the embodiment described herein and the configurations illustrated in the drawings are merely one embodiment in which the disclosure is realized and do not represent all the technical ideas of the disclosure, it should be understood that there may be various equivalents, variations, and applicable examples that can replace them at the time of filing this application.

Although terms such as first, second, A, B, etc. used in the description and the claims may be used to describe various components, the components should not be limited by these terms. These terms are only used to differentiate one component from another. For example, a first component may be referred to as a second component, and similarly, a second component may be referred to as a first component, without departing from the scope of the disclosure. The term ‘and/or’ includes a combination of a plurality of related listed items or any item of the plurality of related listed items.

The terms used in the description and the claims are merely used to describe particular embodiments and are not intended to limit the disclosure. Singular forms are intended to include plural forms unless the context clearly indicates otherwise. In the application, terms such as “comprise,” “comprise,” “have,” etc. should be understood as not precluding the possibility of existence or addition of features, numbers, steps, operations, components, parts, or combinations thereof described herein.

Unless otherwise defined, the phrases “A, B, or C,” “at least one of A, B, or C,” or “at least one of A, B, and C” may refer to only A, only B, only C, both A and B, both A and C, both B and C, all of A, B, and C, or any combination thereof.

Unless being defined otherwise, all terms used herein, including technical or scientific terms, have the same meaning as commonly understood by those skilled in the art to which the disclosure pertains.

Terms such as those defined in commonly used dictionaries should be construed as having a meaning consistent with the meaning in the context of the relevant art, and are not to be construed in an ideal or excessively formal sense unless explicitly defined in the application. In addition, each configuration, procedure, process, method, or the like included in each embodiment of the disclosure may be shared to the extent that they are not technically contradictory to each other.

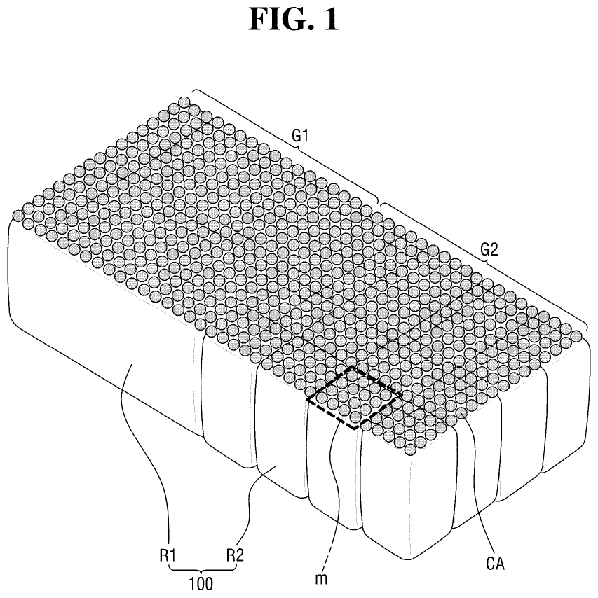

Hereinafter, a solid oxide cell in accordance with an embodiment of the present disclosure will be described with reference to FIGS. 1 to 5.

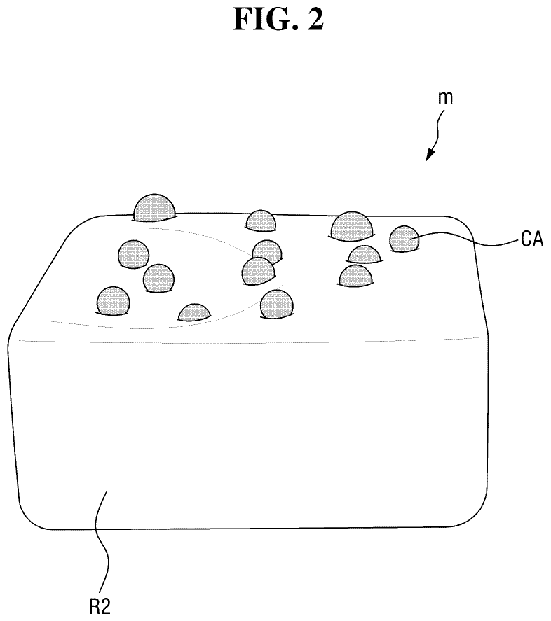

FIG. 1 is a diagram for describing a solid oxide cell in accordance with an embodiment of the present disclosure. FIG. 2 is an enlarged view of the region m of FIG. 1.

Referring to FIGS. 1 and 2, a solid oxide cell in accordance with an embodiment of the present disclosure may include a substrate 100.

The solid oxide cell may operate as a solid oxide fuel cell or as a solid oxide electrolysis cell, depending on the mode of operation. FIGS. 1 and 2 are diagrams after depositing a catalyst material CA on the substrate 100 but before operating the solid oxide cell (e.g., before applying the initial power).

The substrate 100 may be a substrate of an electrode of the solid oxide cell. The substrate 100 may include a first region R1 and a second region R2. The first region R1 and the second region R2 may be a portion of the substrate 100 of the electrode of the solid oxide cell. The substrate 100 may include a plurality of first regions R1 and a plurality of second regions R2.

The first region R1 may include a first material, and the second region R2 may include a second material. The first material and the second material may be different materials. For example, the first material may include a metallic material. For example, the first material may include nickel. For example, the second material may include a rare earth material. For example, the second material may include yttria-stabilized zirconia (YSZ).

The solid oxide cell may include a catalyst material CA on the substrate 100. The catalyst material CA may have been deposited in the form of particles in each of the first region R1 and the second region R2. The catalyst material CA may not form a film on the substrate 100.

The catalyst material CA may include a first catalyst material group G1 deposited in the first region R1 and a second catalyst material group G2 deposited in the second region R2.

The catalyst material CA may be, for example, any one of Pd, Ag, Pt, Au, Ru, and Ir. In the following, an example in which the catalyst material CA is platinum (Pt) will be described.

The first region R1 and the second region R2 of the substrate 100 may be porous regions. The first region R1 and the second region R2 may include a plurality of holes. The size (e.g., diameter) of the plurality of holes may be larger than the size (e.g., diameter) of the catalyst material CA particles. For example, the size of the plurality of holes may be about 1 μm to 2 μm, and the size of the catalyst material CA particles before the solid oxide cell operates may be about 1 nm to 2 nm. The catalyst material CA may have been deposited in the porous regions in the form of particles.

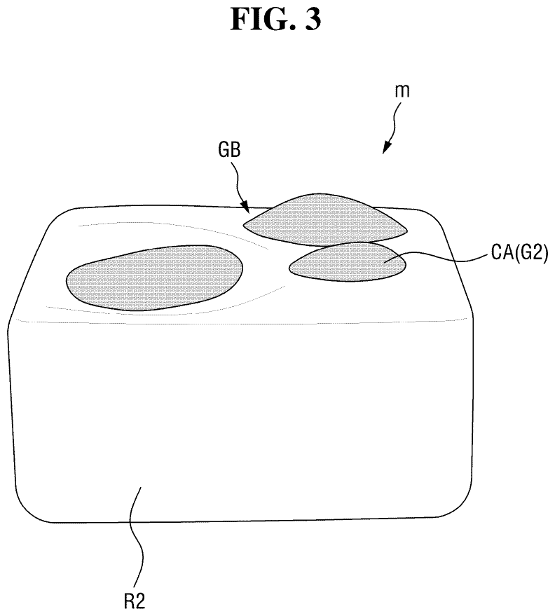

FIG. 3 is an enlarged view of the region m in FIG. 1. FIG. 3 is a diagram of a case where the solid oxide cell operates in a first mode after power is applied to the electrode of the solid oxide cell in the state of FIG. 1 to thereby operate the solid oxide cell.

Referring to FIGS. 1 to 3, power may be applied to the electrode including the substrate 100 of the solid oxide cell in accordance with an embodiment of the present disclosure.

The solid oxide cell may be operated in a first mode and a second mode. The first mode may be, for example, a fuel cell mode for generating electricity. The second mode may be, for example, an electrolysis mode for generating hydrogen.

Based on the solid oxide cell operating in the first mode, the shape of the catalyst material CA that has been present in the form of particles on the substrate 100 may be transformed.

In the first mode, a first form of a catalyst material of the first catalyst material group G1 and a second form of a catalyst material of the second catalyst material group G2 may be different. In the first mode, the first form may be the one in which the catalyst material of the first catalyst material group G1 has been formed into the form of an alloy with the metallic material included in the first region R1. In the first mode, the catalyst material of the first catalyst material group G1 may be maintained in the form of an alloy with the metallic material of the first region R1. The second form may be a more spread-out form than the form of the particles before the operation, as shown in FIG. 3.

In the first mode, the catalyst material of the second catalyst material group G2 may be inserted into a grain boundary GB of a material included in the second region R2. If the material contained in the second region R2 is YSZ, the catalyst material of the second catalyst material group G2 may be inserted into the grain boundary GB of YSZ based on the solid oxide cell operating in the first mode.

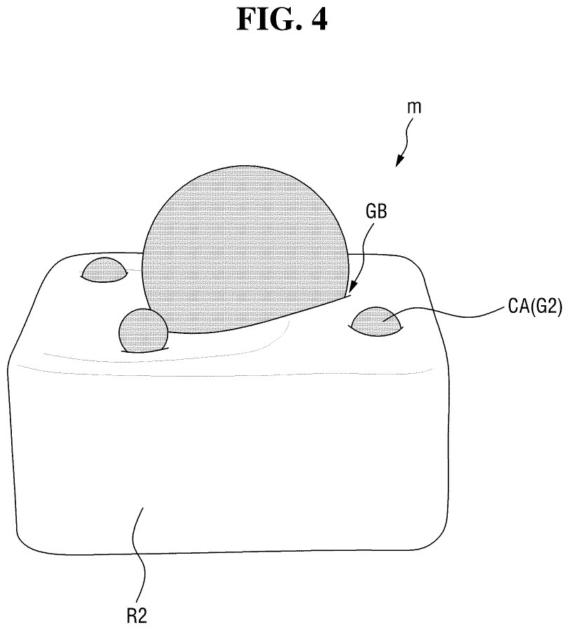

FIG. 4 is an enlarged view of the region m in FIG. 1. FIG. 4 is a diagram of a case where the solid oxide cell operates in the second mode after power is applied to the electrode of the solid oxide cell in the state of FIG. 1 to thereby operate the solid oxide cell.

Referring to FIGS. 1 to 4, power may be applied to the electrode including the substrate 100 of the solid oxide cell in accordance with an embodiment of the present disclosure.

Based on the solid oxide cell operating in the second mode, the shape of the catalyst material CA that has been present in the form of particles on the substrate 100 may be transformed.

In the second mode, the first form of the catalyst material of the first catalyst material group G1 and a third form of the catalyst material of the second catalyst material group G2 may be different. In the second mode, the first form may be the one in which the catalyst material of the first catalyst material group G1 has been formed into the form of an alloy with the metallic material included in the first region R1. In the second mode, the catalyst material of the first catalyst material group G1 may be maintained in the form of an alloy with the metallic material of the first region R1. The third form may be a form that has grown larger due to the agglomeration phenomenon from the particle form before the operation, as shown in FIG. 4.

In the second mode, the catalyst material of the second catalyst material group G2 may not be inserted into the grain boundary GB of the material included in the second region R2. If the material contained in the second region R2 is YSZ, the catalyst material of the second catalyst material group G2 may be present outside the grain boundary GB of YSZ based on the solid oxide cell operating in the second mode.

The second form of the catalyst material of the second catalyst material group G2 in the first mode and the third form of the catalyst material of the second catalyst material group G2 in the second mode may be different from each other. The second form may be a more spread-out form than the third form. The third form may be more agglomerated than the second form and may be closer to a hemispherical form.

The height of the second form in the vertical direction on the basis of the upper surface of the substrate 100 may be less than the height of the third form. The height of the particle form of the catalyst material CA before the solid oxide cell operates may be greater than the height of the second form and less than the height of the third form.

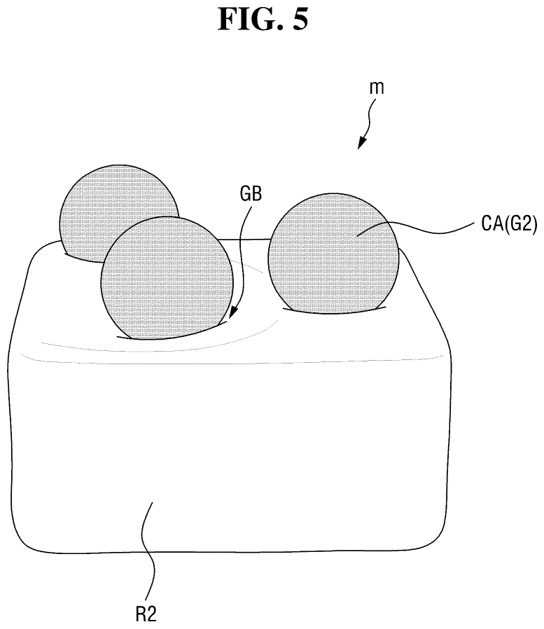

FIG. 5 is an enlarged view of the region m in FIG. 1. FIG. 5 is a diagram of a case where the solid oxide cell operates alternately in the first mode and the second mode after power is applied to the electrode of the solid oxide cell in the state of FIG. 1 to thereby operate the solid oxide cell.

Referring to FIGS. 1 to 5, power may be applied to the electrode including the substrate 100 of the solid oxide cell in accordance with an embodiment of the present disclosure.

The solid oxide cell may be operated alternately in the first mode and the second mode. For example, the solid oxide cell may repeat operating in the first mode, then operating in the second mode, and then operating in the first mode again.

Based on the solid oxide cell operating alternately in the first mode and the second mode, the form of the catalyst material CA in the second region R2 may be maintained in the form of particles having a size within a certain range. For example, while repeating that the catalyst material of the second catalyst material group G2 is transformed into the second form in the first mode, the catalyst material of the second catalyst material group G2 is transformed into the third form when switched to the second mode, and is transformed into the second form when switched back to the first mode, the form of the catalyst material of the second catalyst material group G2 in the second region R2 can be maintained in the form of particles having a size within a certain range.

For example, if the solid oxide cell operates in the first mode, the catalyst material of the second catalyst material group G2 may be inserted into the grain boundary GB. If the solid oxide cell operates in the first mode and then switches to the second mode, the catalyst material of the second catalyst material group G2 may be precipitated from the grain boundary GB.

If the solid oxide cell is operated alternately in the first mode and the second mode, the catalyst material of the second catalyst material group G2 may be, for example, close to a spherical form. If an operation is made alternately in the first mode and the second mode, the catalyst material of the second catalyst material group G2 may have a size (e.g., diameter) of 8 nm to 10 nm.

Even if the solid oxide cell is operated alternately in the first mode and the second mode, the catalyst material of the first catalyst material group G1 can maintain the form of an alloy with the metallic material contained in the first region R1.

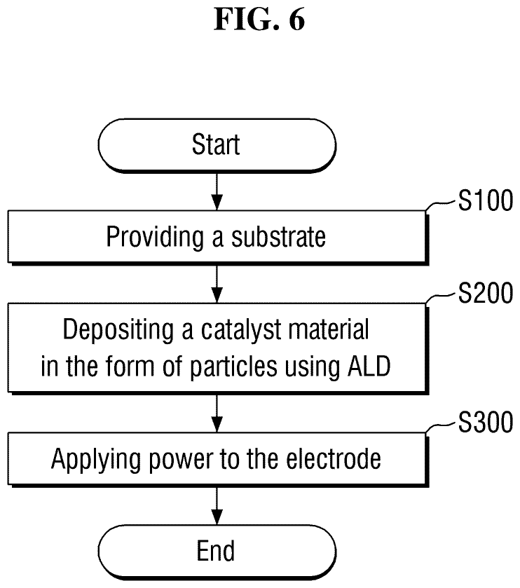

In the following, a method of manufacturing and operating a solid oxide cell in accordance with an embodiment of the present disclosure will be described with reference to FIGS. 6 to 11. For clarity of description, any description that overlaps with what has been described above will be simplified or omitted.

FIG. 6 is a diagram for describing a method of manufacturing and operating a solid oxide cell in accordance with an embodiment of the present disclosure.

Referring to FIG. 6, a method of manufacturing and operating a solid oxide cell in accordance with an embodiment of the present disclosure includes providing a substrate (S100).

The substrate may include a first region containing a first material and a second region containing a second material.

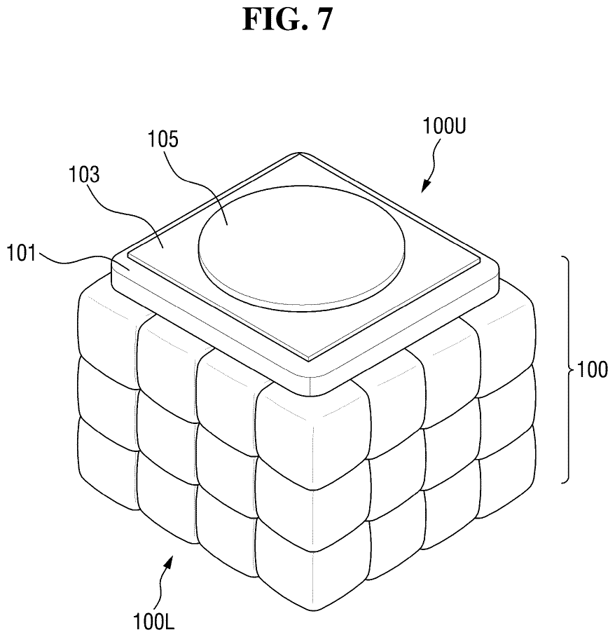

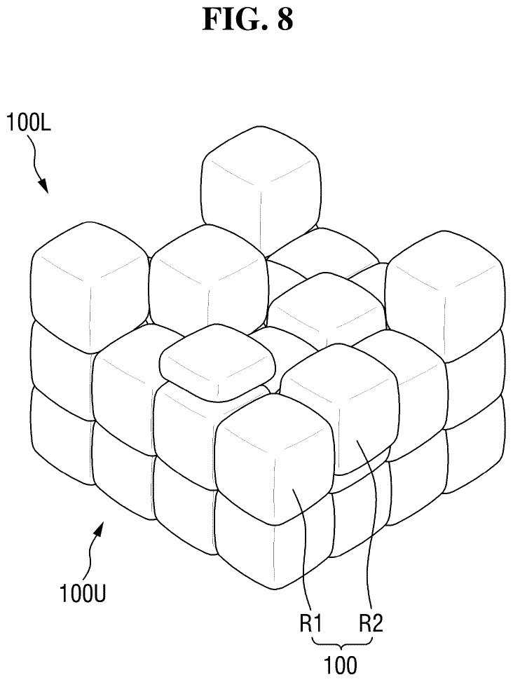

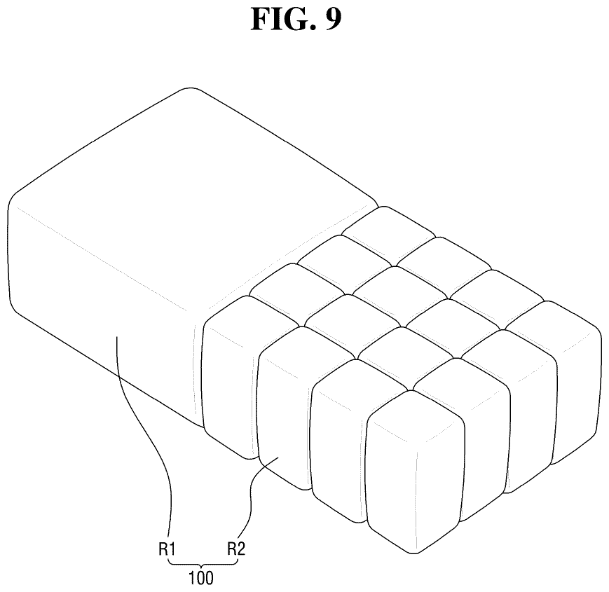

FIGS. 7 to 9 are diagrams for describing step S100 in FIG. 6. FIG. 9 is an enlarged view of the first region and the second region of FIG. 8.

Referring to FIGS. 6 and 7, the substrate 100 may be provided. The substrate 100 may include an upper surface 100U and a lower surface 100L. A support layer 101, an electrolyte 103, and an electrode 105 may be disposed on the upper surface 100U of the substrate 100. The substrate 100 may include, for example, a metal oxide. The substrate 100 may include, for example, a metal oxide and a rare earth element. The substrate 100 may include, for example, NIO-YSZ.

Referring to FIGS. 6 to 8, the providing the substrate (S100) may include reducing the substrate 100. Thereby, the metal oxide may be reduced, resulting in the substrate 100 being porous. For example, the lower surface 100L side of the substrate 100 may become porous due to the reduction. The substrate 100 may include a first region R1 and a second region R2.

Referring to FIGS. 6 to 9, the first region R1 may contain a first material, and the second region R2 may contain a second material. The first region R1 may contain a metallic material after reduction, and the second region R2 may include a rare earth material.

Referring again to FIG. 6, the method of manufacturing and operating a solid oxide cell in accordance with an embodiment of the present disclosure may include depositing a catalyst material in the form of particles using ALD (atomic layer deposition) (S200). The ALD may be performed on the first region and the second region of the substrate.

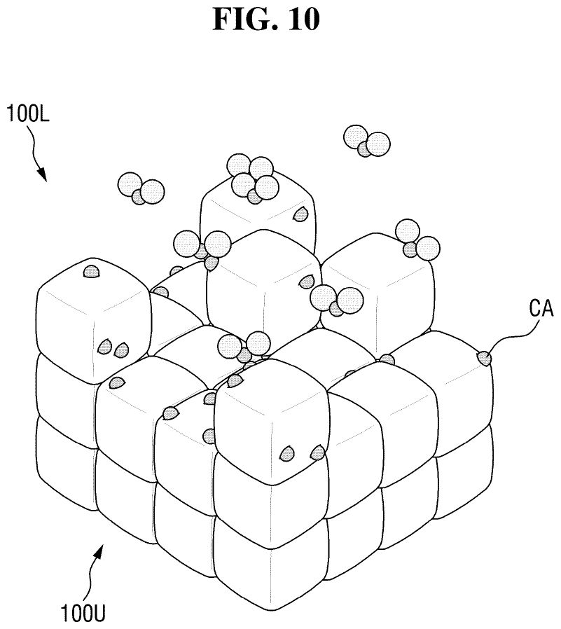

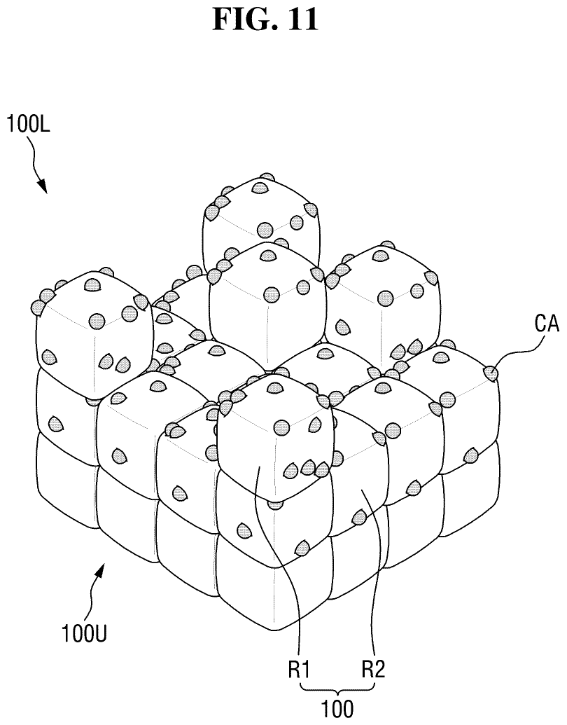

FIGS. 10 and 11 are diagrams for describing step S200 of FIG. 6.

Referring to FIGS. 6 and 10, the ALD may be performed in an oxygen plasma environment. Using the ALD, the catalyst material CA may be deposited in the form of particles in the substrate 100. The catalyst material CA may not be deposited in the form of a film. Since the substrate 100 is porous, the catalyst material CA may also be deposited in the holes.

The catalyst material CA may be deposited in the first region R1 and the second region R2. The catalyst material CA may include a first catalyst material group (G1 in FIG. 1) deposited in the first region R1 and a second catalyst material group (G2 in FIG. 1) deposited in the second region R2. The enlarged view of the first region R1 and the second region R2 after the ALD process has been performed and before operation may be the same as that shown in FIG. 1.

The method of manufacturing and operating a solid oxide cell in accordance with an embodiment of the present disclosure can deposit a catalyst material in a small amount of catalyst by using the ALD process in order to deposit the catalyst material in the form of particles in the substrate. In addition, the method of manufacturing and operating a solid oxide cell in accordance with an embodiment of the present disclosure can improve catalytic reactivity by depositing the catalyst material in the substrate in the form of particles rather than a film.

Referring again to FIG. 6, the method of manufacturing and operating a solid oxide cell in accordance with an embodiment of the present disclosure may include applying power to the electrode (S300). By applying power to the electrode, the solid oxide cell in accordance with an embodiment of the present disclosure may operate in a first mode or a second mode.

The first mode may be a fuel cell mode for generating electricity, and the second mode may be an electrolysis mode for generating hydrogen.

Before power is applied to the electrode of the solid oxide cell, the catalyst material CA may have been deposited as shown in FIGS. 1 and 11. Before power is applied to the electrode of the solid oxide cell, the form of the first catalyst material group G1 in the first region R1 and the form of the second catalyst material group G2 in the second region R2 may be the same, as shown in FIGS. 1 and 11.

After power is applied to the electrode of the solid oxide cell, the form of the catalyst material CA in each of the first region R1 and the second region R2 may change.

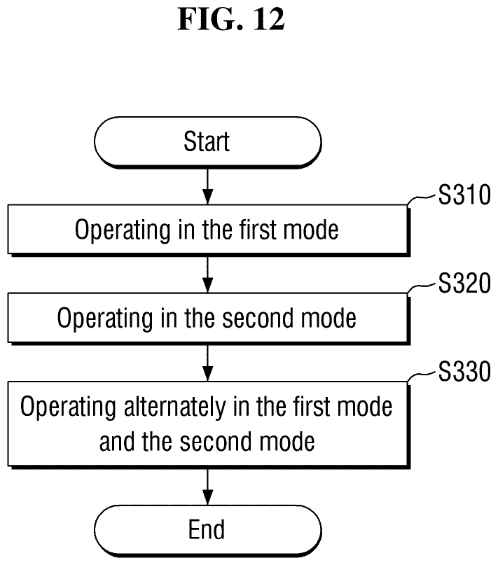

FIG. 12 is a diagram for describing step S300 of FIG. 6.

Referring to FIGS. 3, 6, and 12, the applying the power to the electrode (S300) may include operating in the first mode (S310).

If the solid oxide cell is operated in the first mode, a first form of the first catalyst material group (G1 in FIG. 1) and a second form of the second catalyst material group G2 may become different. If the solid oxide cell is operated in the first mode, the catalyst material of the first catalyst material group (G1 in FIG. 1) may be maintained in the form of an alloy with the metallic material contained in the first region R1. If the solid oxide cell is operated in the first mode, the second form of the second catalyst material group G2 may be different from the first form. Further, the second form may be different from the form of the catalyst material CA immediately after the catalyst material CA is deposited using ALD (FIGS. 1, 2, and 11). If the solid oxide cell is operated in the first mode, the catalyst material of the second catalyst material group G2 may be inserted into the grain boundary GB of the material contained in the second region R2.

Referring to FIGS. 4, 6, and 12, the applying the power to the electrode (S300) may include operating in the second mode (S320).

If the solid oxide cell is operated in the second mode, the first form of the first catalyst material group (G1 in FIG. 1) and a third form of the second catalyst material group G2 may become different. If the solid oxide cell is operated in the second mode, the catalyst material of the first catalyst material group (G1 in FIG. 1) may be maintained in the form of an alloy with the metallic material contained in the first region R1. If the solid oxide cell is operated in the second mode, the third form of the second catalyst material group G2 may be different from the first form. Further, the third form may also be different from the second form in the first mode (see FIGS. 3 and 4). Moreover, the third form may be different from the form of the catalyst material CA immediately after the catalyst material CA is deposited using ALD (FIGS. 1, 2, and 11).

Referring to FIGS. 5, 6, and 12, the applying the power to the electrode (S300) may include operating alternately in the first mode and the second mode (S330).

If the solid oxide cell is operated alternately in the first mode and the second mode, the first form of the first catalyst material group (G1 in FIG. 1) and the form of the second catalyst material group G2 may become different. If the solid oxide cell is operated alternately in the first mode and the second mode, the catalyst material of the first catalyst material group (G1 in FIG. 1) may be maintained in the form of an alloy with the metallic material contained in the first region R1. If the solid oxide cell is operated alternately in the first mode and the second mode, the form of the second catalyst material group G2 may be maintained in the form of particles having a size within a certain range. Further, if the solid oxide cell is operated alternately in the first mode and the second mode, the form of the second catalyst material group G2 may be different from the form of the catalyst material CA immediately after the catalyst material CA is deposited using ALD (FIGS. 1, 2, and 11). If operated alternately in the first mode and the second mode, the catalyst material of the second catalyst material group G2 may have a size (e.g., diameter) of 8 nm to 10 nm.

If the solid oxide cell is operated alternately in the first mode and the second mode, the catalyst material of the second catalyst material group G2 may repeat being inserted into the grain boundary GB of the material contained in the second region R2 and then being precipitated. For example, the catalyst material of the second catalyst material group G2 may be inserted into the grain boundary GB of the material contained in the second region R2 when the solid oxide cell is operated in the first mode, and the catalyst material of the second catalyst material group G2 may be precipitated from the grain boundary GB of the material contained in the second region R2 when the solid oxide cell is switched to the second mode.

Steps S310, S320, and S330 may change in order and performed. For example, the catalyst material CA may be deposited in the form of particles by ALD, and then execution may begin with the second mode as well.

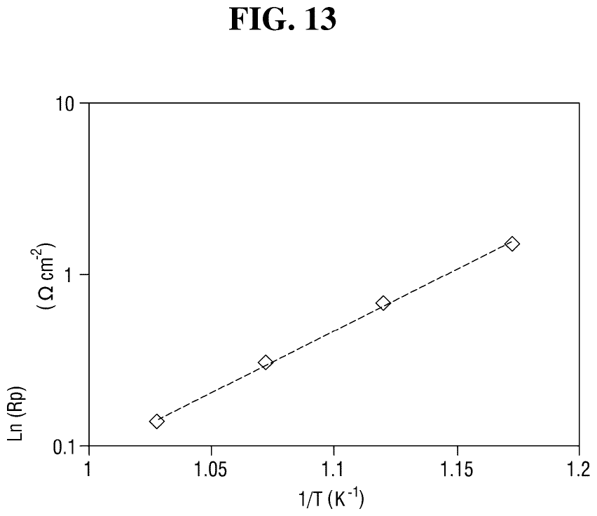

FIG. 13 is a plot for describing the effect of a solid oxide cell in accordance with an embodiment of the present disclosure.

Referring to FIG. 13, as the catalyst material is deposited in the form of particles in the substrate of the solid oxide cell in accordance with an embodiment of the present disclosure and then operation is carried out, the activation energy at which the catalytic reaction occurs is low. The graph in FIG. 13 is an Arrhenius plot, and the slope represents the activation energy.

The catalyst material CA of the substrate 100 of the solid oxide cell in accordance with the embodiment of the present disclosure can have high catalytic reactivity by having its form changed according to the operation mode. Accordingly, the catalyst material of the substrate 100 of the solid oxide cell in accordance with the embodiment of the present disclosure can secure high catalytic reactivity as the form of the catalyst material CA is maintained in the form of FIG. 5 even when operated in a high temperature and high humidity environment.

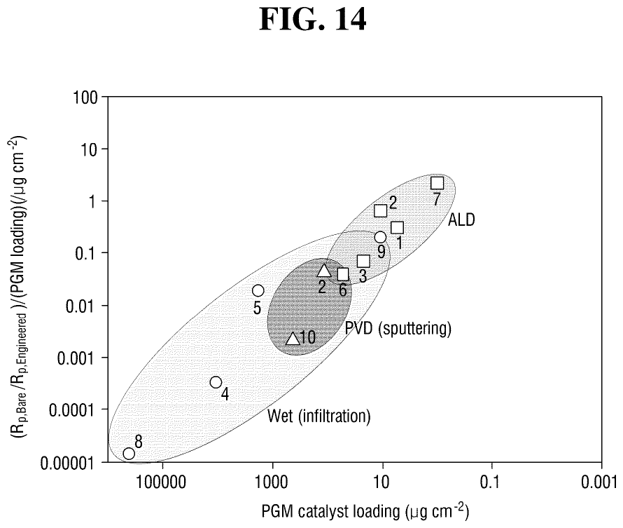

FIG. 14 is a plot for describing the effect of the method of manufacturing and operating a solid oxide cell in accordance with an embodiment of the present disclosure.

Referring to FIG. 14, the Y-axis of the graph in FIG. 14 is a value obtained by dividing the performance increase rate by the loading amount of the catalyst material, and the X-axis is the loading amount of the catalyst material. Here, the catalyst material is a platinum group metal (PGM).

It can be confirmed that the highest performance increase rate relative to the loading amount of the catalyst material can be secured if the catalyst material is deposited on the substrate using ALD, compared to the infiltration method using an aqueous solution and the PVD (physical vapor deposition) method (sputtering method).

The method of manufacturing and operating a solid oxide cell in accordance with an embodiment of the present disclosure can secure improved performance using a small amount of catalyst material by depositing the catalyst material on the substrate in the form of particles using ALD.

While the inventive concept has been particularly shown and described with reference to exemplary embodiments thereof, it will be understood by those of ordinary skill in the art that various changes in form and details may be made therein without departing from the spirit and scope of the inventive concept as defined by the following claims. It is therefore desired that the embodiments be considered in all respects as illustrative and not restrictive, reference being made to the appended claims rather than the foregoing description to indicate the scope of the disclosure.

What is claimed is:

1. A solid oxide cell comprising:
a substrate comprising a first region and a second region; and
a catalyst material deposited in the form of particles in each of the first region and the second region, and comprising a first catalyst material group deposited in the first region and a second catalyst material group deposited in the second region,
wherein power is applied to an electrode including the substrate,
based on operating in a first mode, a first form of a catalyst material of the first catalyst material group and a second form of a catalyst material of the second catalyst material group are different, and
based on operating in a second mode, the first form of the first catalyst material group and a third form of a catalyst material of the second catalyst material group are different.

2. The solid oxide cell of claim 1, wherein the second form and the third form are different.

3. The solid oxide cell of claim 1, wherein based on operating alternately in the first mode and the second mode, the second form and the third form are maintained in the form of particles having a size within a certain range.

4. The solid oxide cell of claim 3, wherein the second form and the third form have a size of 8 nm to 10 nm.

5. The solid oxide cell of claim 1, wherein the first region and the second region are porous regions.

6. The solid oxide cell of claim 5, wherein based on operating in the first mode, the catalyst material of the second catalyst material group is inserted into a grain boundary of a material contained in the second region, and
based on having switched from the first mode to the second mode, the catalyst material of the second catalyst material group is precipitated from the grain boundary of the material contained in the second region.

7. The solid oxide cell of claim 6, wherein based on operating in the first mode, the catalyst material of the first catalyst material group is maintained in the form of an alloy with a metallic material of the first region, and
based on having switched from the first mode to the second mode, the catalyst material of the first catalyst material group is maintained in the form of the alloy with the metallic material of the first region.

8. A method of manufacturing and operating a solid oxide cell, comprising:
providing a substrate comprising a first region containing a first material and a second region containing a second material;
depositing a catalyst material in the first region and the second region in the form of particles using atomic layer deposition (ALD); and
operating in one of a first mode and a second mode by applying power to an electrode including the substrate.

9. The method of claim 8, wherein the catalyst material comprises a first catalyst material group deposited in the first region in the form of particles and a second catalyst material group deposited in the second region in the form of particles, and
wherein the operating in one of the first mode and the second mode by applying power to the electrode including the substrate comprises:
operating in the first mode so that a first form of a catalyst material of the first catalyst material group and a second form of a catalyst material of the second catalyst material group are different; and
operating in the second mode so that the first form of the first catalyst material group and a third form of a catalyst material of the second catalyst material group are different.

10. The method of claim 9, wherein the second form and the third form are different.

11. The method of claim 9, wherein the operating in one of the first mode and the second mode by applying power to the electrode including the substrate comprises:
operating alternately in the first mode and the second mode so that the second form and the third form are maintained in the form of particles having a size within a certain range.

12. The method of claim 8, wherein the first region and the second region are porous regions.

13. The method of claim 12, wherein the catalyst material comprises a first catalyst material group deposited in the first region in the form of particles and a second catalyst material group deposited in the second region in the form of particles, and
wherein the operating in one of the first mode and the second mode by applying power to the electrode including the substrate comprises:
operating in the first mode so that a catalyst material of the second catalyst material group is inserted into a grain boundary of the second material; and
switching from the first mode to the second mode so that the catalyst material of the second catalyst material group is precipitated from the grain boundary of the second material.

14. The method of claim 13, wherein in the operating in the first mode, a catalyst material of the first catalyst material group is maintained in the form of an alloy with a metallic material of the first region, and
in the switching from the first mode to the second mode, the catalyst material of the first catalyst material group is maintained in the form of the alloy with the metallic material of the first region.

15. A method of manufacturing and operating a solid oxide cell, comprising:
providing a substrate comprising a first region and a second region in which a catalyst material is deposited in the form of particles;
operating in one of a first mode and a second mode by applying power to an electrode including the substrate,
wherein the catalyst material comprises a first catalyst material group deposited in the first region in the form of particles and a second catalyst material group deposited in the second region in the form of particles, and
wherein the operating in one of the first mode and the second mode by applying power to the electrode including the substrate comprises:
operating in the first mode so that a first form of a catalyst material of the first catalyst material group and a second form of a catalyst material of the second catalyst material group are different; and
operating in the second mode so that the first form of the first catalyst material group and a third form of a catalyst material of the second catalyst material group are different.

16. The method of claim 15, further comprising:
depositing the catalyst material in the first region and the second region in the form of particles using atomic layer deposition (ALD)

17. The method of claim 15, wherein the operating in one of the first mode and the second mode by applying power to the electrode including the substrate comprises:
operating alternately in the first mode and the second mode so that the second form and the third form are maintained in the form of particles having a size within a certain range.

18. The method of claim 15, wherein the first region and the second region are porous regions.

19. The method of claim 18, wherein the operating in the first mode comprises setting to the first mode so that the catalyst material of the second catalyst material group is inserted into a grain boundary of a material contained in the second region, and
wherein the operating in one of the first mode and the second mode by applying power to the electrode including the substrate comprises:
switching from the first mode to the second mode so that the catalyst material of the second catalyst material group is precipitated from the grain boundary of the material contained in the second region.

20. The method of claim 19, wherein in the operating in the first mode, the catalyst material of the first catalyst material group is maintained in the form of an alloy with a metallic material of the first region, and
in the switching from the first mode to the second mode. the catalyst material of the first catalyst material group is maintained in the form of the alloy with the metallic material of the first region.
